(19) United States
(12) Patent Application Publication
(10) Pub. No.: US 2023/0008253 A1
(43) Pub. Date: Jan. 12, 2023

(54) Innovation In High Performance Electro-Chromic Device Manufacturing Method

(71) Applicant: ATATÜRK ÜNIVERSITESI BILIMSEL ARASTIRMA PROJELERI BIRIMI, Erzurum (TR)

(72) Inventors: Emre GUR, Erzurum (TR); Soheil MOBTAKERI, Erzurum (TR); Saman HABASHYANI, Erzurum (TR)

(21) Appl. No.: 17/784,101

(22) PCT Filed: Jan. 21, 2021
(86) PCT No.: PCT/TR2021/050051

§ 371 Date: Jun. 9, 2022

(30) Foreign Application Priority Data
Jul. 9, 2020 (TR) 2020/10936

(51) Int. Cl. C23C 14/34; G02F 1/1524; G02F 1/1523; C23C 14/18; C23C 14/08; C23C 14/58; C03C 17/36

(52) U.S. Cl. CPC C23C 14/3464; G02F 1/1524; G02F 1/1525; C23C 14/185; C23C 14/086; C23C 14/5853; C03C 17/3649; C03C 17/3671; C03C 2217/948; C03C 2218/154; C03C 2218/322

(57) ABSTRACT

The invention relates to the manufacturing method of high performance electro-chromic devices containing transition metal oxide based compounds, wherein it comprises the steps of enlarging of the metal contact with Pt (Platinum) (1) sputtering method on one edge of the 80-150 nm thick Indium-Tin oxide alloy (ITO) (2), which was previously enlarged on the glass (3) by the sputter method, growing vertical nano-wall structures at 15-25 mTorr, 300-500° C. substrate temperature and at 3-45 minutes intervals on glass (3) with sputter method, by using transition metal chalcogen targets on previously enlarged ITO (2) with a thickness of 80-150 nm, oxidizing the grown structures in the oxidizing furnace for 10-60 minutes under oxygen gas in the temperature range 300-450° C., preparing the electro-chromic device by placing a counter glass/ITO (80-150 nm) in propylene carbonate (PC) to face 1 Mole/Liter Lithium perchlorate (LiClO4) ion-conducting electrolyte (6) with a 0.5-1 mm distance between them and closing it.

### TECHNICAL FIELD

The invention relates to the manufacturing method of high performance electro-chromic devices containing transition metal oxide based compounds.

In particular, the invention relates to the method of manufacturing electro-chromic materials with sputtering method from nanostructures with enhanced surface area by producing vertical nano-wall transition metal oxide-based WO₃ (tungsten trioxide) and MoO₃ (molybdenum trioxide) structures with a novel method, especially in order to develop smart glass technology.

### KNOWN STATE OF THE ART

Today, electro-chromic glasses, which we can call smart glass, are used in many areas. Especially mobile phones, television screens, billboards, sunglasses and rear view mirrors are just a few of their fields of use. Electro-chromism is a phenomenon that is the change of the color of the electro-chromic thin film coated on the glass in a very short time by the applied voltage and the electro-chromic materials return to their original transparent state by reversing the applied voltage.

Furthermore, smart glasses produced from these materials provide energy saving and are used in new generation screens. An important feature of these screens lies in the fact that they preserve their state by resetting the applied voltage. This allows them to be used in areas such as making curtains or billboards from these smart glasses.

Many electro-chromic materials are presently available. In general, transition metal oxides are materials that are showing electro-chromic properties in this sense. The most important of these are WO₃ and MoO₃ due to their superior performance (short turn on/off time, long durability, no performance deterioration with time, coloration efficiency, etc.) that they exhibit.

The most important performance parameters for these smart glasses are the speed of coloration after the voltage is applied and the speed of turning back into transparent state. In addition to these, the number of repetitions that the device can work without degradation is also an important parameter.

Finally, another important parameter is the coloring efficiency. The change in optical transmittance value is desired to be quite high when the device becomes colored after the voltage is applied, and electro-chromic glasses with 50%-60% change are presently available. The change in these transmittance values is not high enough. There are electro-chromic glasses operating in the industry at 5 s or more. This time is actually long and it is one of the major barriers that prevents the commercialization of these materials.

An electro-chromic glass manufacturing method is mentioned in the patent application number TR2018/18520. This method is an electro-chromic glass manufacturing method whereby the first and second layers of conductive oxide, electro-chromic electrode, solid electrolyte, counter electrode are subjected to heat treatment by being exposed to irradiation together at certain wavelengths; the mentioned method is costly and it cannot provide the desired benefit.

Therefore, because of the adverse situations described above and also due to the inadequacy of the available solutions, there is a need to make an improvement in the related technical field.

### PURPOSE OF THE INVENTION

The invention has been made by being inspired by the present situations and aims to solve the adverse issues mentioned above.

The priority purpose of the invention is to reduce the turn on/off time of the electro-chromic device to less than 5 seconds.

Another purpose of the invention is to produce an electro-chromic device that can operate safely for long periods without creating a continuous cost to the user.

Still another purpose of the invention is to increase the coloration efficiency of the electro-chromic device to the order of 60% by making sure that the change in optical transmittance value is quite high.

Furthermore, another purpose of the invention is to create a cost-effective and efficient production method for manufacturing electro-chromic devices.

The structural and characteristic features as well as all advantages of the invention will be understood more clearly by means of the figures given below and the detailed description provided in reference to these figures; and therefore the evaluation should be made by taking these figures and detailed explanations into consideration.

### DRAWINGS TO HELP UNDERSTAND THE INVENTION

FIG. 1 illustrates the steps of the electro-chromic device manufacturing method, which is the subject of the invention.

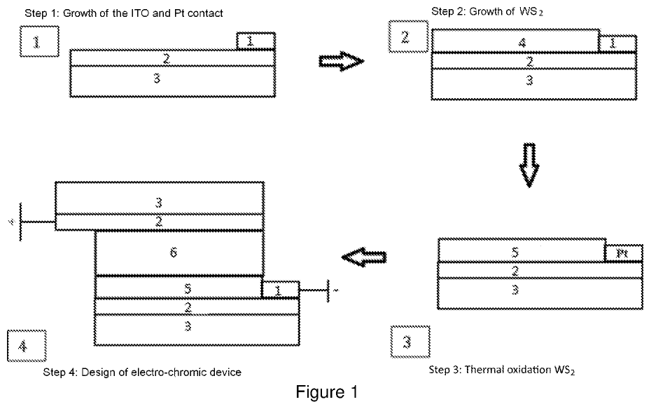

FIG. 2 is the perspective view of the electro-chromic device, which is the subject of the invention.

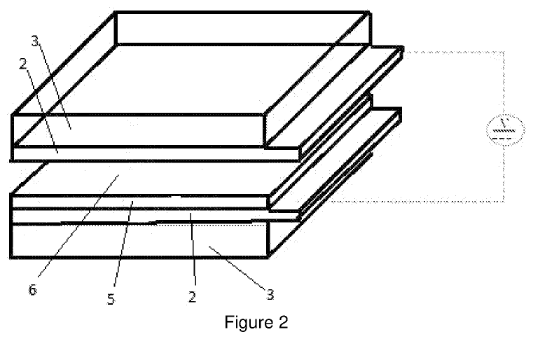

### DESCRIPTION OF PART REFERENCES

1. Pt
2. ITO
3. Glass
4. WS₂
5. WO₃
6. Ion conductive electrolyte (LiCI04)

### DETAILED DESCRIPTION OF THE INVENTION

In this detailed description, the preferred embodiments for the electro-chromic device manufacturing method of the invention are described for the sole purpose of providing a better understanding of the subject.

The subject of the invention involves the manufacturing of vertical nano-wall WO₃ (Tungsten trioxide) (5) and MoO₃ (Molybdenum trioxide) structures with an original method using the sputtering method, which is a coating method suitable for the industry, together with thermal oxidation method. With the usage of these two conventional method together, It becomes possible to produce of electro-chromic materials with nano structures with very large surface areas. It has been possible to manufacture WO₃ (5) based electro-chromic devices with turn on/off time shorter than 5 s, which can work thousands of hours that have coloration efficiency in the order of 60%.

The production stages of the specially produced chromic layers such as WO₃ (5), MoO₃ and the device, which provide for the high performance operation of the constructed electro-chromic devices, are explained step by step below;

First, the metal contact is enlarged with Pt (Platinum) (Al would be also possible for this layer) (1) sputtering method on one edge of the 80-150 nm thick ITO (Indium-Tin oxide alloy) (2), which was previously grown on the glass (3) by the sputter method. Glass (3) and ITO (2) electrodes are used as counter electrodes in electro-chromic devices. At this point, these electro-chromic devices can also be produced using 80-150 nm FTO (fluorine doped Tin Oxide alloy).

Then, by using sputter method, transition metal chalcogens (WS₂ (Tungsten disulfide) (4), Molybdenum disulfide (MoS₂) etc.) were used on ITO (2) with a thickness of 80-150 nm, which were previously grown on glass (3) to grow vertical nano-wall structures at 15-50 mTorr, 200-500° C. substrate temperature and at 1-45 minutes intervals.

The grown structures are oxidized in the oxidizing furnace for 5-120 minutes under oxygen gas controlled with mass flow controller between 100-1000 sccm in the temperature range 300-400° C. This temperature range varies according to the thickness of the grown material such as MoS₂ and WS₂ etc. In order to find out the correct oxidation time, in-situ transmission and conductivity measurements might be required, which we used in our experiments.

Afterwards, the electro-chromic device is prepared by placing a counter glass/ITO (80-150 nm) in propylene carbonate (PC) to face 1 Mol/Liter Lithium perchlorate (LiClO₄) ion-conducting electrolyte (6) with a 0.5-1 mm distance between them and closing it. Li ions are contained in this ion conductive (6) solution. Also, these devices can be implemented using Cs-based, Na-based electrolytes and etc.

Glass (3)/ITO (2)/Electro-chromic layer, vertical nano wall WO₃(5), MoO₃ etc. is transition metal oxide layer. It allows Li ions to enter these layers to form a high performance electro-chromic device.

After the device is manufactured, a power supply is connected with Pt (1) electrodes to the glass (3)/ITO (2)/Pt (1) layer in order to operate the device. −3 V is applied to the device (it might be lower depending on the thickness of the chromic layer). After the voltage is applied, the Li⁺ ions in the ion conductive electrolyte (6) layer enter the glass (3)/ITO (2)/electro-chromic layer, and over time the transparent glass begins to color. With the application of +3 V to the electrodes, the colored glass becomes transparent.

The performance data of the electro-chromic device having the Glass/ITO/WO₃/electrolyte/ITO/Glass structure, which was manufactured with the method comprising the subject of the patent, is shown in the figure above. This data shows the dynamic transmittance data of the electro-chromic device at 700 nm wavelength. In the first 30-second part of the figure, −3 V was applied to the electro-chromic device and it was observed that the transmittance of the device fell below 10% from the initial transmittance value. This is the coloration state of the device and the device turns black. The first 67% part of this decrease is termed as the coloration time of the device and, as seen in the figure, this time is 2.28 s. In the second 30-second part, +3 V was applied to the device and the device was made to return to its former state. The turn-on time of the device was determined as 1.28 s here. This data shows the superior performance of the device produced by the method which is the subject of the patent. Better device performances become possible by changing the thickness of the chromic layers.

1. The invention relates to the manufacturing method of high performance electro-chromic devices containing transition metal oxide based compounds, wherein it comprises the following steps;
Growing of the metal contact with Pt (Platinum) (1) sputtering method on one edge of the 80-150 nm thick Indium-Tin oxide alloy (ITO) (2), which was previously grown on the glass (3) by the sputter method, to preserve the conductivity of ITO during oxidation,
Growing vertical nano-wall structures at 15-50 mTorr, 200-500° C. substrate temperature and at 1-45 minutes intervals on glass (3) with sputtering method, by using transition metal chalcogen targets on previously grown ITO (2) with a thickness of 80-150 nm,
Oxidizing the grown structures in the oxidizing furnace for 5-120 minutes under oxygen gas controlled with mass flow controller between 100-1000 sccm in the temperature range 300-400° C.,
Preparing the electro-chromic device by placing a counter glass/ITO (80-150 nm) in propylene carbonate (PC) to face 1 Mol/Liter Lithium perchlorate (LiClO₄) ion-conducting electrolyte (6) with a 0.5-1 mm distance between them and closing it.

2. The electro-chromic device manufacturing method according to claim 1, wherein the transition metal chalcogens used on ITO (2) are tungsten disulfide (4) (WS₂) and molybdenum disulfide (MoS₂).

3. The electro-chromic device manufacturing method according to claim 1, wherein FTO (fluorine doped Tin Oxide Alloy) with a thickness of 80-150 nm is used at the sputtering stage instead of Indium-Tin Oxide Alloy (ITO) (2) with a thickness of 80-150 nm.

4. The electro-chromic device manufacturing method according to claim 1, wherein using Cs-based and Na-based electrolytes is used instead of lithium perchlorate (LiClO₄) ion conductive electrolyte (6).

5. This invention is a high performance electro-chromic device manufacturing method, wherein it comprises a glass (3)/ITO (2)/electro-chromic layer that allows Li ions from ion conductive electrolyte (LiClO₄) (6) to enter the transition metal oxide layer to produce high performance.

6. The electro-chromic device mentioned in claim 5, wherein the transition metal oxide layer comprises transition metal oxides.

7. The electro-chromic device mentioned in claim 5, wherein the transition metal oxide layer preferably comprises WO₃ (5) and MoO₃.
